(19) United States
(12) Patent Application Publication
(10) Pub. No.: US 2018/0192552 A1
(43) Pub. Date: Jul. 5, 2018

(54) HEAT-DISSIPATING SYSTEM AND METHOD OF WHOLE CABINET SERVER SYSTEM

(71) Applicant: BEIJING BAIDU NETCOM SCIENCE AND TECHNOLOGY CO., LTD., Beijing (CN)

(72) Inventors: Xianguang TAN, Beijing (CN); Guofeng Chen, Beijing (CN); Jiajun Zhang, Beijing (CN)

(73) Assignee: BEIJING BAIDU NETCOM SCIENCE AND TECHNOLOGY CO., LTD., Beijing (CN)

(21) Appl. No.: 15/860,590

(22) Filed: Jan. 2, 2018

(30) Foreign Application Priority Data
Jan. 4, 2017 (CN) 201710003494.2

(51) Int. Cl. H05K 7/20

(52) U.S. Cl. CPC H05K 7/20781; H05K 7/20736; H05K 7/20272; H05K 7/20254; H05K 7/20772

(57) ABSTRACT

The present disclosure provides a heat-dissipating system and method of a whole cabinet server system. The system comprises: a whole cabinet server system, a water-cooling plate, a water-cooling coil pipe and a fan; the water-cooling plate is disposed on each designated heat-generating element in each server of the whole cabinet server system; the water-cooling plate is configured to use low-temperature water therein to take away heat generated by the designated heat-generating element; the fan is configured to produce low-temperature air stream which flows through the whole cabinet server system and the water-cooling coil pipe in turn; the water-cooling coil pipe is configured to cool air stream that have absorbed the heat of the whole cabinet server system as low-temperature air stream. The solutions of the present disclosure can be applied to improve the heat-dissipating efficiency and reduce the costs of implementation.

The present application claims the priority of Chinese Patent Application No. 201710003494.2, filed on Jan. 4, 2017, with the title of “Heat-dissipating system and method of whole cabinet server system”.

### FIELD OF THE DISCLOSURE

The present disclosure relates to heat-dissipating technologies, and particularly to a heat-dissipating system and method of a whole cabinet server system.

### BACKGROUND OF THE DISCLOSURE

In a whole cabinet server system, components in the server generate a lot of heat upon operation. Heat dissipation processing needs to be performed in time to ensure safe and reliable operation of the system.

An air-cooling heat-dissipating manner is usually employed in the prior art, i.e., low-temperature air stream, blown by a fan, flows through the whole cabinet server system, exchanges heat with heat-generating components in the server, and absorbs heat, thereby lowering the temperature of components.

However, the above manner has certain problems in practical application, for example:

1) The air-cooling heat-dissipating manner exhibits a low heat-dissipating efficiency. If the heat-dissipating efficiency needs to be improved, the flow of air needs to be increased. However, this causes abrupt increase of energy consumption and costs.

2) In the air-cooling heat-dissipating manner, air entering the server needs to be kept at a lower temperature, so a dedicated Computer Room Air Handling (CRAH) or air-conditioning terminal device needs to be arranged in the computer room to cool air in the computer room, which increases the costs of implementation.

### SUMMARY OF THE DISCLOSURE

In view of the above, the present disclosure provides a heat-dissipating system and method of a whole cabinet server system, which can improve the heat-dissipating efficiency and reduce the costs of implementation.

Specific technical solutions are as follows:

A heat-dissipating system of a whole cabinet server system, comprising:

a whole cabinet server system, a water-cooling plate, a water-cooling coil pipe and a fan;

the water-cooling plate is disposed on each designated heat-generating element in each server of the whole cabinet server system;

the water-cooling plate is configured to use low-temperature water therein to take away heat generated by the designated heat-generating element;

the fan is configured to produce low-temperature air stream which flows through the whole cabinet server system and the water-cooling coil pipe in turn;

the water-cooling coil pipe is configured to cool air stream that have absorbed the heat of the whole cabinet server system as low-temperature air stream.

According to a preferred embodiment of the present disclosure,

the designated heat-generating element comprise main heat-generating elements in the server, including a Central Processing Unit CPU and Graphics Processing Unit GPU;

the low-temperature water comprises cooling water and chilled water.

According to a preferred embodiment of the present disclosure,

the water-cooling coil pipe is further configured to provide low-temperature water for the water-cooling plate.

According to a preferred embodiment of the present disclosure,

the heat-dissipating system further comprises a Coolant Distribution Unit CDU;

the CDU is configured to provide low-temperature water for the water-cooling coil pipe, obtain water stream that is drained out of each water-cooling plate and has absorbed heat, and discharge heat into ambient environment after treatment.

According to a preferred embodiment of the present disclosure,

the heat-dissipating system further comprises an ingress water manifold and a return water manifold;

the ingress water manifold is configured to convey the low-temperature water obtained from the water-cooling coil pipe to each water-cooling plate;

the return water manifold is configured to return water stream that is drained out of each water-cooling plate and has absorbed heat, to the CDU.

A heat-dissipating method of a whole cabinet server system, comprising:

disposing a water-cooling plate on each designated heat-generating element in each server of the whole cabinet server system so that low-temperature water in the water-cooling plate is used to take away heat generated by the designated heat-generating elements;

providing a water-cooling coil pipe for the whole cabinet server system, and providing a fan for the whole cabinet server system, to produce low-temperature air stream, the air stream flowing through the whole cabinet server system and the water-cooling coil pipe in turn, the water-cooling coil pipe cooling the air stream that have absorbed the heat of the whole cabinet server system as low-temperature air stream.

According to a preferred embodiment of the present disclosure,

the designated heat-generating element comprise main heat-generating elements in the server, including a Central Processing Unit CPU and Graphics Processing Unit GPU;

the low-temperature water comprises cooling water and chilled water.

According to a preferred embodiment of the present disclosure,

the method further comprises: configuring the water-cooling coil pipe to provide low-temperature water for the water-cooling plate.

According to a preferred embodiment of the present disclosure, the method further comprises:

providing the whole cabinet server system with a Coolant Distribution Unit CDU to provide low-temperature water for the water-cooling coil pipe, obtain water stream that is drained out of each water-cooling plate and has absorbed heat, and discharge heat into ambient environment after treatment.

According to a preferred embodiment of the present disclosure, the method further comprises:

providing the whole cabinet server system with an ingress water manifold to convey the low-temperature water obtained from the water-cooling coil pipe to each water-cooling plate;

providing the whole cabinet server system with a return water manifold to return water stream that is drained out of each water-cooling plate and has absorbed heat, to the CDU.

To conclude, with the solution of the present disclosure being employed, the water-cooling plate and the like are provided, and the water-cooling heat-dissipating manner having an excellent cooling capability is employed to dissipate heat for the whole cabinet server system to improve the heat-dissipating efficiency. Furthermore, the low-temperature air stream generated by the fan may be further used to dissipate heat for the whole cabinet server system. In addition, after absorbing the heat of the whole cabinet server system, the low-temperature air stream generated by the fan may be cooled by the water-cooling coil pipe back again to the low-temperature air stream without providing a dedicated CRAH or air-conditioning terminal device as in the prior art, thereby substantially reducing the costs of implementation.

### BRIEF DESCRIPTION OF DRAWINGS

FIG. 1 is a structural schematic view of an embodiment of a heat-dissipating system of a whole cabinet server system according to the present disclosure;

FIG. 2 is a flow chart of an embodiment of a heat-dissipating method of a whole cabinet server system according to the present disclosure.

### DETAILED DESCRIPTION OF PREFERRED EMBODIMENTS

Solutions of the present disclosure will be further described in detail by describing embodiments with reference to figures to make the technical solutions of the present disclosure clearer and more apparent.

### Embodiment 1

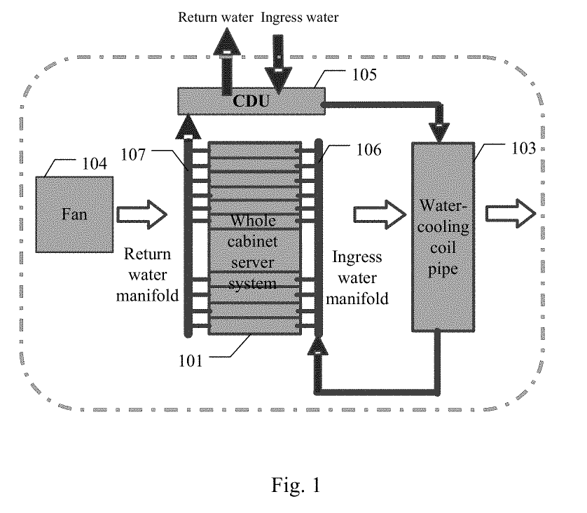

FIG. 1 is a structural schematic view of a heat-dissipating system of a whole cabinet server system according to an embodiment of the present disclosure. As shown in FIG. 1, the heat-dissipating system comprises: a whole cabinet server system 101, a water-cooling coil pipe 103 and a fan 104, and further comprises a water-cooling plate 102 which is not shown in the figure to simplify the figure.

The water-cooling plate 102 is disposed on each designated heat-generating element in each server of the whole cabinet server system 101.

The water-cooling plate 102 is configured to use low-temperature water therein to take away heat generated by the designated heat-generating element.

The fan 104 is configured to produce low-temperature air stream which flows through the whole cabinet server system 101 and the water-cooling coil pipe 103 in turn.

The water-cooling coil pipe 103 is configured to cool air stream that have absorbed the heat of the whole cabinet server system 101 as low-temperature air stream, and may be further configured to provide low-temperature water for the water-cooling plate 102.

As shown in FIG. 1, the heat-dissipating system may further comprise a Coolant Distribution Unit (CDU) 105, an ingress water manifold 106 and a return water manifold 107.

The CDU 105 is configured to provide low-temperature water for the water-cooling coil pipe 103, obtain water stream that is drained out of each water-cooling plate 102 and has absorbed heat, and discharge heat into ambient environment after treatment.

The ingress water manifold 106 is configured to convey the low-temperature water obtained from the water-cooling coil pipe 103 to each water-cooling plate 102.

The return water manifold 107 is configured to return water stream that is drained out of each water-cooling plate 102 and has absorbed heat, to the CDU 105.

The whole cabinet server system 101 comprises a plurality of servers, and the water-cooling plate 102 may be disposed on a designated heat-generating element in each of the servers.

The water-cooling plate 102 may be fixed on the designated heat-generating element in a manner for example by screws, and a surface of the water-cooling plate 102 may be made in contact with a surface of the designated heat-generating element.

The designated heat-generating element usually refers to main heat-generating elements in the server, for example, a Central Processing Unit (CPU) and Graphics Processing Unit (GPU).

The heat-generating elements are usually in a one-to-one relationship with the water-cooling plates, for example, one CPU corresponds to one water-cooling plate.

Usually, one whole cabinet server system 101 respectively corresponds to one water-cooling coil pipe 103, one CDU 105, one ingress water manifold 106 and one return water manifold 107, but one CDU 105 may correspond to one or more whole cabinet server system 101.

To simplify the figure, FIG. 1 only shows one whole cabinet server system 101. No matter whether the CDU 105 corresponds to one or more cabinet server systems 101, its operation manner is the same, i.e., the CDU 105 is connected with the water-cooling coil pipe 103 to provide low-temperature water for the water-cooling coil pipe 103, and is connected with the return water manifold 107 to obtain water stream that is returned by the return water manifold 107, drained out of the water-cooling plate 102 and has absorbed heat, and discharge heat into ambient environment after treatment. How to treat is of the prior art.

The low-temperature water may comprise cooling water, chilled water or the like. Hereunder the cooling water is taken as an example to illustrate.

The water-cooling coil pipe 103 is connected with the CDU 105 and the ingress water manifold 106 to obtain the cooling water from the CDU 105 and then convey it to the ingress water manifold 106.

The ingress water manifold 106 may respectively distribute the cooling water obtained from the water-cooling coil pipe 103 to each server in the whole cabinet server system 101, namely, respectively convey the cooling water to each water-cooling plate 102 in each server.

The cooling water in each water-cooling plate 102 exchanges heat with the heat-generating element, has absorbed heat generated by the heat-generating element, and then returns to the CDU 105 through the return water manifold 107.

To conclude the above introduction, a water flow direction may be obtained as follows: CDU 105→water-cooling coil pipe 103→ingress water manifold 106→water-cooling plate 102→return water manifold 107→CDU 105.

As compared with the prior art, the solution of the present disclosure employs the water-cooling heat dissipation manner. Since water cooling has an excellent cooling capability, it has a higher heat dissipating efficiency.

In addition, on this basis, as shown in FIG. 1, the fan 104 may be used to generate low-temperature air stream, the low-temperature air stream flows through the whole cabinet server system 101, exchanges heat with the heat-generating elements (mainly referring to elements not provided with the water cooling plate 102) in each server, has absorbed heat, then further flows through the water-cooling coil pipe 103, and contacts with pipe outer walls and nearby cold water, thereby achieving the purpose of temperature reduction and being cooled into the low-temperature air stream.

Specific positions of the fan 104 and water-cooling coil pipe 103 may be decided depending on actual needs, but need to satisfy the following: the low-temperature air stream generated by the fan 104 flows through the whole cabinet server system 101 and the water-cooling coil pipe 103 in turn.

The fan 104 usually refers to a fan group formed by a plurality of fans, for example, a fan group formed by 30 fans.

The low-temperature air stream generated by the fan 104 has absorbed the heat of the whole cabinet server system 101, then exchanges heat with the water-cooling coil pipe 103, and the heat is finally taken away by the cooling water in the water-cooling coil pipe 103.

As such, heat generated by all elements in each server in the whole cabinet server system 101 is taken away by the cooling water, so that the heat dissipation efficiency is improved.

Furthermore, in the prior art, a dedicated CRAH or air-conditioning terminal device needs to be provided in the computer room to cool air in the room so that the fan can produce low-temperature air stream. After the above processing manner is employed, the water-cooling coil pipe 103 may be used to implement air cooling to obtain desired low-temperature air stream without additionally providing the CRAH or air-conditioning terminal device, thereby substantially reducing the costs of implementation.

It needs to be appreciated that components in the heat-dissipating system shown in FIG. 1, such as the water-cooling plate 102, the water-cooling coil pipe 103, the fan 104, the CDU 105, the ingress water manifold 106 and return water manifold 107, all are known devices/elements in the prior art, and their specific models may be decided depending on actual needs.

The above introduces a system embodiment. The solution of the invention will be further described below through a method embodiment.

### Embodiment 2

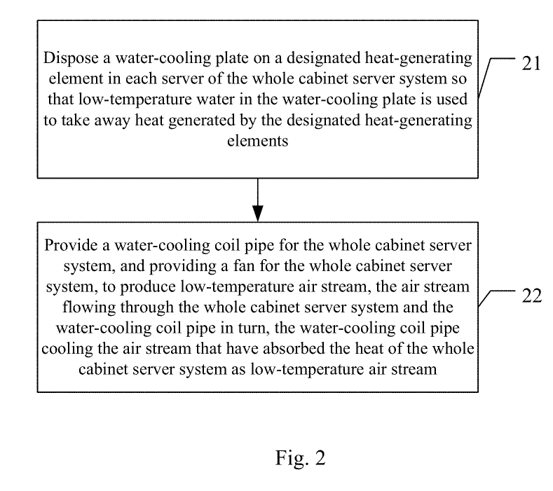

FIG. 2 is a flow chart of an embodiment of a heat-dissipating method of a whole cabinet server system according to the present disclosure, comprising the following specific implementation mode.

In 21, the water-cooling plate is disposed on each designated heat-generating element in each server of the whole cabinet server system so that the low-temperature water in the water-cooling plate is used to take away the heat generated by the designated heat-generating elements.

In 22, the water-cooling coil pipe is provided for the whole cabinet server system, and the fan is provided for the whole cabinet server system, to produce low-temperature air stream. The air stream flows through the whole cabinet server system and the water-cooling coil pipe in turn, and the water-cooling coil pipe cools the air stream that have absorbed the heat of the whole cabinet server system as low-temperature air stream.

The designated heat-generating element comprises main heat-generating elements in the server, including CPU, GPU and the like; the low-temperature water may comprise cooling water, chilled water or the like.

The water-cooling coil pipe may be used to provide low-temperature water for the water-cooling plate.

In addition, the whole cabinet server system may further be provided with the CDU to provide low-temperature water for the water-cooling coil pipe, obtain water stream that is drained out of each water-cooling plate and has absorbed heat, and discharge heat into ambient environment after treatment.

Additionally, the whole cabinet server system may further be provided with the ingress water manifold to convey the low-temperature water obtained from the water-cooling coil pipe to each water-cooling plate;

The whole cabinet server system may further be provided with the return water manifold to return water stream that is drained out of each water-cooling plate and has absorbed heat, to the CDU.

To conclude, with the solution of the present disclosure being employed, the water-cooling plate and the like are provided, and the water-cooling heat-dissipating manner having an excellent cooling capability is employed to dissipate heat for the whole cabinet server system to improve the heat-dissipating efficiency. Furthermore, the low-temperature air stream generated by the fan may be further used to dissipate heat for the whole cabinet server system. In addition, after absorbing the heat of the whole cabinet server system, the low-temperature air stream generated by the fan may be cooled by the water-cooling coil pile back to the low-temperature air stream without providing a dedicated CRAH or air-conditioning terminal device as in the prior art, thereby substantially reducing the costs of implementation.

In the embodiments provided by the present disclosure, it should be understood that the revealed apparatus and method can be implemented through other ways. For example, the above-described embodiments for the apparatus are only exemplary, e.g., the division of the units is merely logical one, and, in reality, they can be divided in other ways upon implementation.

The units described as separate parts may be or may not be physically separated, the parts shown as units may be or may not be physical units, i.e., they can be located in one place, or distributed in a plurality of network units. One can select some or all the units to achieve the purpose of the embodiment according to the actual needs.

Further, in the embodiments of the present disclosure, functional units can be integrated in one processing unit, or they can be separate physical presences; or two or more units can be integrated in one unit. The integrated unit described above can be implemented in the form of hardware, or they can be implemented with hardware plus software functional units.

The aforementioned integrated unit in the form of software function units may be stored in a computer readable storage medium. The aforementioned software function units are stored in a storage medium, including several instructions to instruct a computer device (a personal computer, server, or network equipment, etc.) or processor to perform some steps of the method described in the various embodiments of the present disclosure. The aforementioned storage medium includes various media that may store program codes, such as U disk, removable hard disk, read-only memory (ROM), a random access memory (RAM), magnetic disk, or an optical disk.

What are stated above are only preferred embodiments of the present disclosure, not intended to limit the disclosure. Any modifications, equivalent replacements, improvements and the like made within the spirit and principles of the present disclosure, should all be included in the extent of protection of the present disclosure.

What is claimed is:

1. A heat-dissipating system of a whole cabinet server system, wherein the system comprises:
a whole cabinet server system, a water-cooling plate, a water-cooling coil pipe and a fan;
the water-cooling plate is disposed on a designated heat-generating element in each server of the whole cabinet server system;
the water-cooling plate is configured to use low-temperature water therein to take away heat generated by the designated heat-generating element;
the fan is configured to produce low-temperature air stream which flows through the whole cabinet server system and the water-cooling coil pipe in turn;
the water-cooling coil pipe is configured to cool air stream that have absorbed the heat of the whole cabinet server system as low-temperature air stream.

2. The heat-dissipating system according to claim 1, wherein
the designated heat-generating element comprises a Central Processing Unit CPU and Graphics Processing Unit GPU;
the low-temperature water comprises cooling water and chilled water.

3. The heat-dissipating system according to claim 1, wherein
the water-cooling coil pipe is further configured to provide low-temperature water for the water-cooling plate.

4. The heat-dissipating system according to claim 3, wherein
the heat-dissipating system further comprises a Coolant Distribution Unit CDU;
the CDU is configured to provide low-temperature water for the water-cooling coil pipe, obtain water stream that is drained out of each water-cooling plate and has absorbed heat, and discharge heat into ambient environment after treatment.

5. The heat-dissipating system according to claim 4, wherein
the heat-dissipating system further comprises an ingress water manifold and a return water manifold;
the ingress water manifold is configured to convey the low-temperature water obtained from the water-cooling coil pipe to each water-cooling plate respectively;
the return water manifold is configured to return water stream that is drained out of each water-cooling plate and has absorbed heat, to the CDU.

6. A heat-dissipating method of a whole cabinet server system, wherein the method comprises:
disposing a water-cooling plate on a designated heat-generating element in each server of the whole cabinet server system so that low-temperature water in the water-cooling plate is used to take away heat generated by the designated heat-generating elements;
providing a water-cooling coil pipe for the whole cabinet server system, and providing a fan for the whole cabinet server system, to produce low-temperature air stream, the air stream flowing through the whole cabinet server system and the water-cooling coil pipe in turn, the water-cooling coil pipe cooling the air stream that have absorbed the heat of the whole cabinet server system as low-temperature air stream.

7. The method according to claim 6, wherein
the designated heat-generating element comprises a Central Processing Unit CPU and Graphics Processing Unit GPU;
the low-temperature water comprises cooling water and chilled water.

8. The method according to claim 6, wherein
the method further comprises: using the water-cooling coil pipe to provide low-temperature water for the water-cooling plate.

9. The method according to claim 8, wherein
the method further comprises:
providing the whole cabinet server system with a Coolant Distribution Unit CDU to provide low-temperature water for the water-cooling coil pipe, obtain water stream that is drained out of each water-cooling plate and has absorbed heat, and discharge heat into ambient environment after treatment.

10. The method according to claim 9, wherein
the method further comprises:
providing the whole cabinet server system with an ingress water manifold to convey the low-temperature water obtained from the water-cooling coil pipe to each water-cooling plate respectively;
providing the whole cabinet server system with a return water manifold to return water stream that is drained out of each water-cooling plate and has absorbed heat, to the CDU.
